(19) United States
(12) Patent Application Publication
(10) Pub. No.: US 2026/0333895 A1
(43) Pub. Date: Oct. 22, 2026

(54) OPTICAL SENSOR MODULE AND MANUFACTURING METHOD THEREOF

(71) Applicant: Ennostar Corporation, Hsinchu City (TW)

(72) Inventors: Shiou-Yi KUO, Hsinchu City (TW); Te-Chung WANG, Hsinchu City (TW)

(21) Appl. No.: 19/645,868

(22) Filed: Apr. 13, 2026

(30) Foreign Application Priority Data
Apr. 16, 2025 (TW) 114114471

(51) Int. Cl. H10F 39/10

(52) U.S. Cl. CPC H10F 39/107

(57) ABSTRACT

The present disclosure discloses an optical sensor module and a manufacturing method thereof. The optical sensor module includes a supporting layer, an optical sensor unit, a plurality of conductive pillars, and a patterned shielding layer. The supporting layer includes an upper surface and a lower surface opposite to each other. The optical sensor unit is disposed on the upper surface. The plurality of conductive pillars penetrates the supporting layer and is electrically connected to the optical sensor unit. The patterned shielding layer is located above the optical sensor unit and includes an opening directly located above the optical sensor unit.

### REFERENCE TO RELATED APPLICATION

This application claims the right of priority based on TW Application Serial No. 114114471, filed on Apr. 16, 2025, and the content of which is hereby incorporated by reference in its entirety.

### TECHNICAL FIELD

The application relates to an optical sensor module and a method for manufacturing the optical sensor module.

### DESCRIPTION OF BACKGROUND ART

In the prior art, for an optical sensor module including a light-emitting element and an optical sensor element, it is customary to use the light-emitting element and the optical sensor element that have already been wire-bonded, to dispose on a semiconductor substrate. The light-emitting element and the optical sensor element are co-encapsulated with a transparent molding material, thereby providing protection without affecting the transmission of optical signals. Subsequently, additional optical structures may be incorporated or the package size may be optimized to meet the product requirement for the optical communication.

In view of the design trend toward overall thinning of the consumer electronics devices, further reducing the overall package size of optical sensor modules has become a top priority in the product development. Accordingly, manufacturers have sought, by various approaches, to reduce the size of the optical sensor module including the light-emitting element and the optical sensor element. However, in the prior art, the light-emitting element and the optical sensor element that have been wire-bonded occupy a certain volume, and they are encapsulated with molding material to provide the necessary protection and fixation. This structure therefore imposes substantial constraints on further reduction in thickness or size of the optical sensor module after packaging.

In view of the above, there is a need to provide an improved structure and process for the optical sensor module to achieve overall miniaturization, so as to better meet the needs of practical applications.

### SUMMARY OF THE APPLICATION

The disclosure provides an optical sensor module, including a supporting layer, an optical sensor unit, a plurality of conductive pillars, and a patterned shielding layer. The supporting layer includes an upper surface and a lower surface opposite to each other. The optical sensor unit is disposed on the upper surface of the supporting layer. The plurality of conductive pillars penetrates through the upper surface of the supporting layer and extends to the lower surface. The plurality of conductive pillars is electrically connected to the optical sensor unit. The patterned shielding layer is located above the optical sensor unit and includes an opening located directly above the optical sensor unit.

In some embodiments, the optical sensor module further includes an insulating layer disposed between the optical sensor unit and the patterned shielding layer, and the thickness of the insulating layer is 1 µm to 5 µm.

In some embodiments, the optical sensor unit includes a plurality of contacts which directly contacts the plurality of conductive pillar.

In some embodiments, the patterned shielding layer includes silicon, metal or photoresist.

In some embodiments, when the patterned shielding layer includes silicon, the thickness of the patterned shielding layer is 10 µm to 30 µm or 20 µm to 40 µm.

In some embodiments, when the patterned shielding layer includes metal, the thickness of the patterned shielding layer is 0.1 µm to 3 µm.

In some embodiments, when the patterned shielding layer includes photoresist, the thickness of the patterned shielding layer is 2 µm to 8 µm or 3 µm to 5 µm.

The disclosure also provides a method for manufacturing an optical sensor module, which includes the following steps: forming an etching stop layer on a substrate; forming an optical sensor unit on the etching stop layer; forming a plurality of conductive pillars on the optical sensor unit; filling a support material among the plurality of conductive pillars to form a supporting layer; and forming a patterned shielding layer on the optical sensor unit, wherein the optical sensor unit is disposed between the patterned shielding layer and the supporting layer.

In some embodiments, the step of forming the patterned shielding layer includes thinning the substrate; and etching the substrate to form an opening, wherein the opening is located directly above the optical sensor unit.

In some embodiments, the step of forming the patterned shielding layer includes removing the substrate to expose the etching stop layer; forming a patterned mask on the exposed etching stop layer; and etching the patterned mask to form the patterned shielding layer which includes an opening located directly above the optical sensor unit.

### BRIEF DESCRIPTION OF THE DRAWINGS

For ease of understanding, the drawings and the detailed descriptions thereof may be referred to concurrently when reading the present disclosure. Through the specific embodiments described herein and with reference to the corresponding drawings, the specific embodiments of the present disclosure are explained in detail to illustrate the operating principles thereof. In addition, for clarity, the features in the drawings may not be depicted to scale; therefore, the dimensions of certain features in some drawings may be intentionally exaggerated or reduced.

FIGS. 1-6 illustrate the cross-sectional schematic diagrams of the manufacturing method of the optical sensor module at different process steps according to an embodiment of the present disclosure.

FIGS. 7 and 8 illustrate the cross-sectional schematic diagrams of the manufacturing method of the optical sensor module at different process steps according to other embodiments of the present disclosure.

FIG. 9A illustrates a top view schematic diagram of the optical sensor module according to an embodiment of the present disclosure.

FIGS. 9B and 9C illustrate the enlarged schematic diagrams of the region R in FIG. 9A.

### DETAILED DESCRIPTION OF PREFERRED EMBODIMENTS

The present disclosure provides several different embodiments that may be used to implement various features of the present disclosure. For the sake of simplicity, the present disclosure also describes examples of specific components and arrangements. The purpose of providing these embodiments is merely illustrative and is not intended to impose any limitation. Various embodiments in the present disclosure may use repeated reference numerals and/or textual annotations. The use of such repeated reference numerals and annotations is intended to make the description more concise and clear, and is not intended to indicate any relationship between different embodiments and/or configurations.

In addition, spatially relative terms used in the present disclosure, such as “under”, “lower”, “below”, “above”, “on”, “upper”, “top”, “bottom”, and similar terms, are used for ease of description to describe the relative relationship between one element or feature and another (or multiple) element(s) or feature(s) in the figures. Apart from the orientation shown in the figures, these spatially relative terms are also used to describe the orientation of the elements in use and during operation. As the orientation of the element changes (e.g., rotated by 90 degrees or to other orientations), the corresponding spatial descriptions are to be interpreted in a similar manner.

Although the present disclosure uses the terms first, second, third, and so forth to describe elements, components, regions, layers, and/or sections, it should be understood that such elements, components, regions, layers, and/or sections are not to be limited by these terms. These terms are only used to distinguish one element, component, region, layer, and/or section from another, and do not imply any sequential order, nor do they indicate the arrangement order between the elements or the sequence in manufacturing processes. Therefore, without departing from the scope of the specific embodiments of the present disclosure, an element, component, region, layer, or section described as “first” herein may also be referred to as a “second” element, component, region, layer, or section.

The terms “about” or “substantially” as referred to in the present disclosure generally indicate within 20% of a given value or range, preferably within 10%, more preferably within 5%, or within 3%, 2%, 1%, or 0.5%. It should be noted that the numerical values provided in the specification are approximate values, meaning that even in the absence of explicit use of the terms “about” or “substantially,” such meanings may be implied.

The terms “coupled,” “coupling,” or “electrically connected” as referred to in the present disclosure include any direct or indirect electrical connection means. For example, when the text describes a first component as being coupled to a second component, it means that the first component may be directly electrically connected to the second component, or indirectly electrically connected to the second component via other devices or connecting means.

Although the following description of the present disclosure is provided using specific embodiments, the principles of the present disclosure may also be applied to other embodiments. Furthermore, to avoid obscuring the spirit of the present invention, certain details are omitted, and such omitted details fall within the knowledge of those skilled in the relevant art.

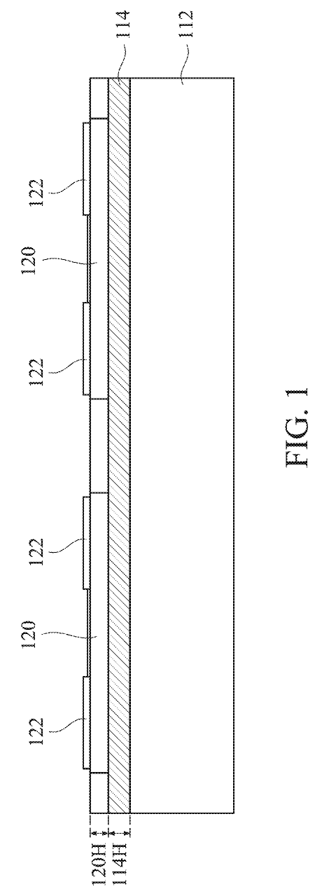

The disclosure provides a method for manufacturing an optical sensor module. FIGS. 1-6 illustrate the schematic cross-sectional views of the manufacturing method of an optical sensor module 10 at different process steps according to an embodiment of the disclosure. Although the method disclosed herein is described below using a series of operations or steps, the order of these operations or steps should not be construed as a limitation of this disclosure. For example, some operations or steps may be performed in a different order and/or simultaneously with other steps. Furthermore, it is not necessary to perform all the illustrated operations, steps, and/or features to achieve the implementation of this disclosure. In addition, each operation or step described herein may include several sub-steps or actions.

Refer to FIG. 1 first. An etching stop layer 114 is formed on the substrate 112. In some embodiments, the substrate 112 includes a flexible substrate, a rigid substrate, or a combination thereof, but the disclosure is not limited thereto. In some embodiments, the substrate 112 includes silicon, quartz, glass, sapphire, ceramic, polyimide (PI), polycarbonate (PC), polypropylene (PP), polyethylene terephthalate (PET), other suitable materials, or combinations thereof, but the disclosure is not limited thereto. In some embodiments, the substrate 112 includes a metal-glass fiber composite board or a metal-ceramic composite board, but the disclosure is not limited thereto. In some embodiments, the substrate 112 includes an opaque substrate, a semi-transparent substrate, or a transparent substrate, but the disclosure is not limited thereto. In some embodiments, the etching stop layer 114 includes an insulating layer. Specifically, the etching stop layer 114 includes a light-transmitting insulating layer. For example, the etching stop layer 114 may include silicon dioxide, silicon nitride, or other suitable materials, but the disclosure is not limited thereto. In some embodiments, the thickness 114H of the etching stop layer 114 may be from 1 µm to 5 µm, for example, 2 µm, 3 µm, or 4 µm.

Referring to FIG. 1, a light-receiving layer (not shown) is formed on the etching stop layer 114. The light-receiving layer includes a plurality of optical sensor units 120 located on the etching stop layer 114. The optical sensor units 120 may be spaced apart from each other or arranged continuously. Specifically, the light-receiving surfaces of the plurality of optical sensor units 120 face the etching stop layer 114. In the embodiment, the light-receiving surfaces of the plurality of optical sensor units 120 are in direct contact with the etching stop layer 114. In some embodiments, the optical sensor units 120 may be any element capable of converting the light signal into the electrical signal. In some embodiments, the optical sensor units 120 may include a photodiode, a phototransistor, a metal-semiconductor-metal photodetector (MSM photodetector), or any other suitable optical sensor element, but the disclosure is not limited thereto. In some embodiments, these optical sensor units 120 may be arranged in an array or matrix. It is understood that each optical sensor unit 120 includes a plurality of contacts 122, and the contacts 122 are located on the side opposite to the light-receiving surface. In some embodiments, the contact 122 includes conductive material, such as silver (Ag), gold (Au), tin (Sn), aluminum (Al), copper (Cu), molybdenum (Mo), tungsten (W), chromium (Cr), nickel (Ni), platinum (Pt), titanium (Ti), alloys of the aforementioned metals, other suitable materials, or combinations thereof, but the disclosure is not limited thereto. In some embodiments, the thickness 120H of the optical sensor unit 120 can be from 1 µm to 10 µm, for example, 3 µm, 5 µm, or 7 µm.

In some embodiments, the micro optical sensor unit 120 includes a silicon layer having an n-type region (not shown), a p-type region (not shown), and an i-type region (not shown) located between the n-type and p-type regions, wherein the n-type, i-type, and p-type regions are arranged along a horizontal direction. The n-type region includes a highly doped n-type semiconductor material and is formed on one side of the micro optical sensor unit 120. The p-type region includes a highly doped p-type semiconductor material and is formed on the other side of the micro optical sensor unit 120. The n-type and p-type regions can be formed by ion implantation or diffusion. The i-type region is located between the n-type and p-type regions and includes a doping concentration lower than the n-type or p-type regions, or the i-type region is near intrinsic. Under a bias, a depletion region is formed to facilitate the absorption of photons and the generation of electron-hole pairs. Under a driving by a built-in or an applied electric field, electrons and holes respectively move to the n-type and p-type regions and are collected, thereby generating a photocurrent. The contacts 122 can be located on a portion of the n-type and p-type regions to provide the electrical connection or the external bias.

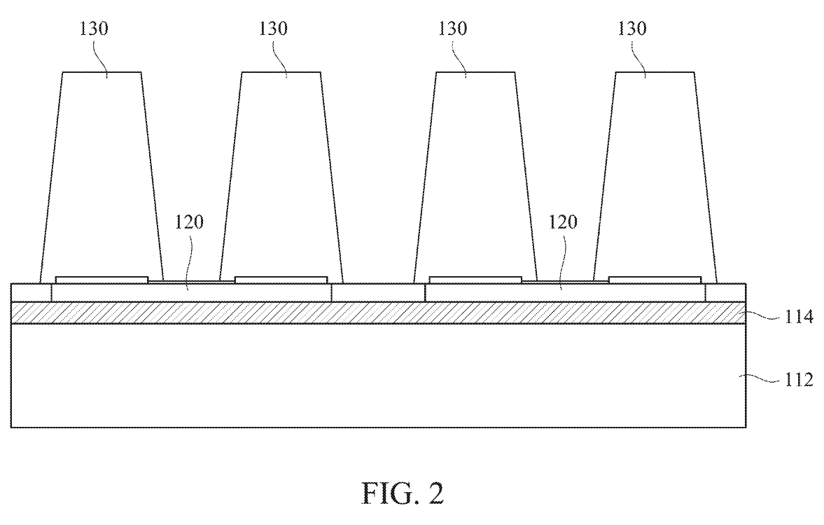

Next, referring to FIG. 2, a plurality of conductive pillars 130 is formed on the optical sensor unit 120. Specifically, these conductive pillars 130 are disposed on the contacts 122 for electrical connection with the optical sensor unit 120. In some embodiments, the conductive pillars 130 directly contact the contacts 122 of the optical sensor unit 120. In some embodiments, the vertical projection area of each conductive pillar 130 on the substrate 112 is at least greater than or equal to the vertical projection area of each contact 122 on the substrate 112. In some embodiments, the conductive pillar 130 completely covers the contact 122. In other embodiments, the conductive pillar 130 may partially cover the contact 122. In other words, the conductive pillar 130 and the contact 122 may be laterally offset from each other, but the conductive pillar 130 and the contact 122 still need to be partially in contact to achieve electrical connection. The spacing between two adjacent conductive pillars 130 for electrical connecting with the micro optical sensor unit 120 can be adjusted according to the wire layout density or heat dissipation conditions. For example, the spacing can be between 20 µm and 60 µm.

In some embodiments, the conductive pillar 130 includes a conductive cylinder or a conductive support structure having other geometric shape, but the disclosure is not limited thereto. In some embodiments, the material of the conductive pillar 130 includes gold, silver, copper, aluminum, iron, tin, nickel, alloys of the above metals, or other suitable conductive materials, but the disclosure is not limited thereto.

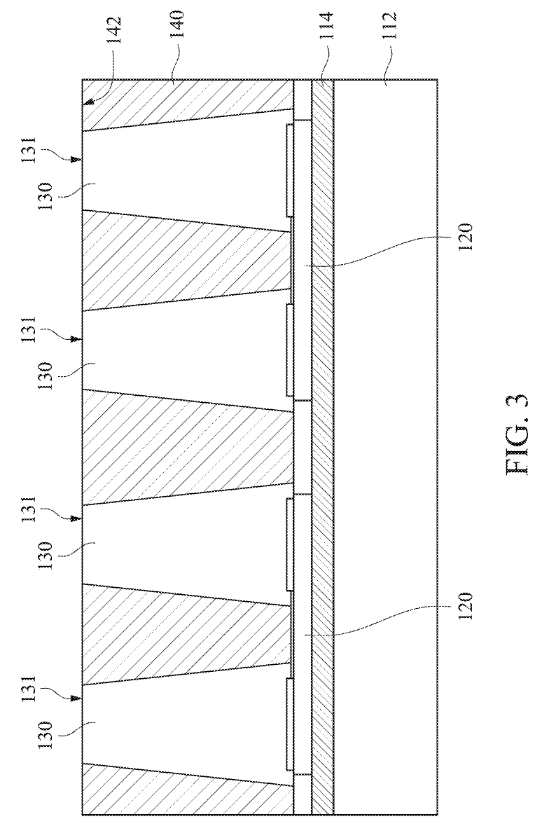

Next, referring to FIG. 3, a support material is filled among the conductive pillars 130 to form a supporting layer 140. In some embodiments, the surface 142 of the supporting layer 140 is substantially flush with the surface 131 of the conductive pillar 130. In some embodiments, the supporting layer 140 is an electrically insulating layer. In some embodiments, the supporting layer 140 may include a light-transmitting insulating material, a semi-light-transmitting insulating material, or an opaque insulating material. In some embodiments, the thickness of the supporting layer 140 is between 50 µm and 130 µm or between 70 µm and 110 µm. In some embodiments, the supporting layer 140 may be selected from epoxy molding compound (EMC), polyimide (PI), epoxy, silicone, or other suitable support materials, but the disclosure is not limited thereto.

In some embodiments, the thickness ratio of the conductive pillar 130 to the micro optical sensor unit 120 is between 1:5 and 1:20. In some embodiments, the conductive pillar 130 includes an aspect ratio between 1:1 and 1:5.

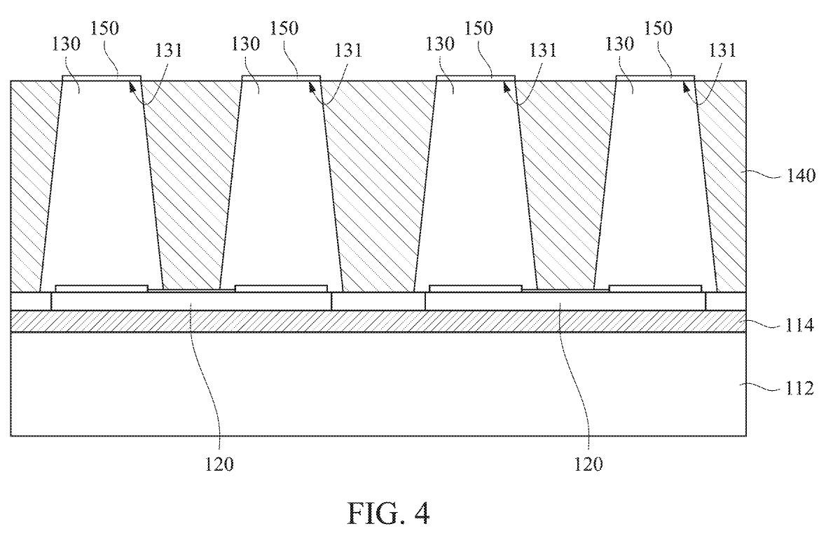

Next, referring to FIG. 4, the solder pads 150 are formed on the surface 131 of the conductive pillars 130 exposed from the supporting layer 140. In some embodiments, the solder pads 150 can be formed on the surface 131 of the conductive pillars 130 exposed from the supporting layer 140 using surface-mount technology (SMT). In other words, the solder pads 150 are in direct contact with the conductive pillars 130. In some embodiments, the material of the solder pad 150 includes gold, silver, copper, aluminum, iron, tin, nickel, alloys of the above metals, or other suitable conductive materials, but the disclosure is not limited thereto.

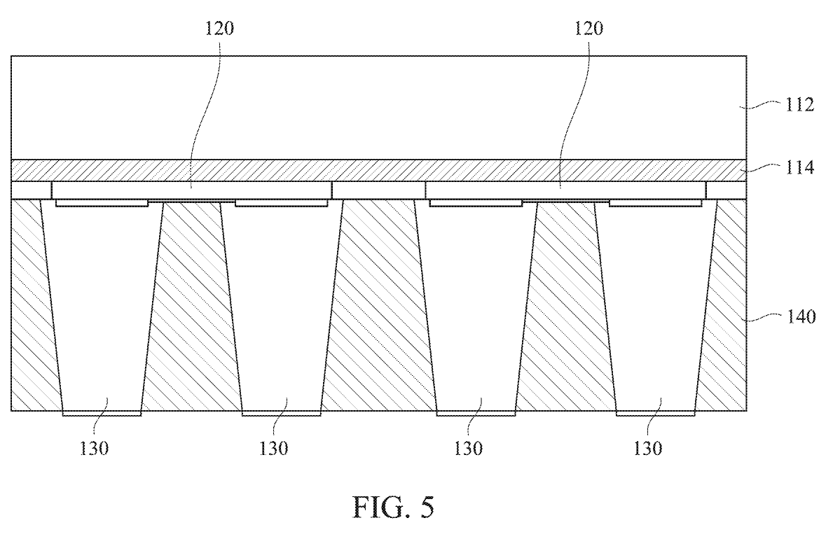

Next, referring to FIG. 5, flip the semi-finished structure formed as shown in FIG. 4 so that the substrate 112 faces upward.

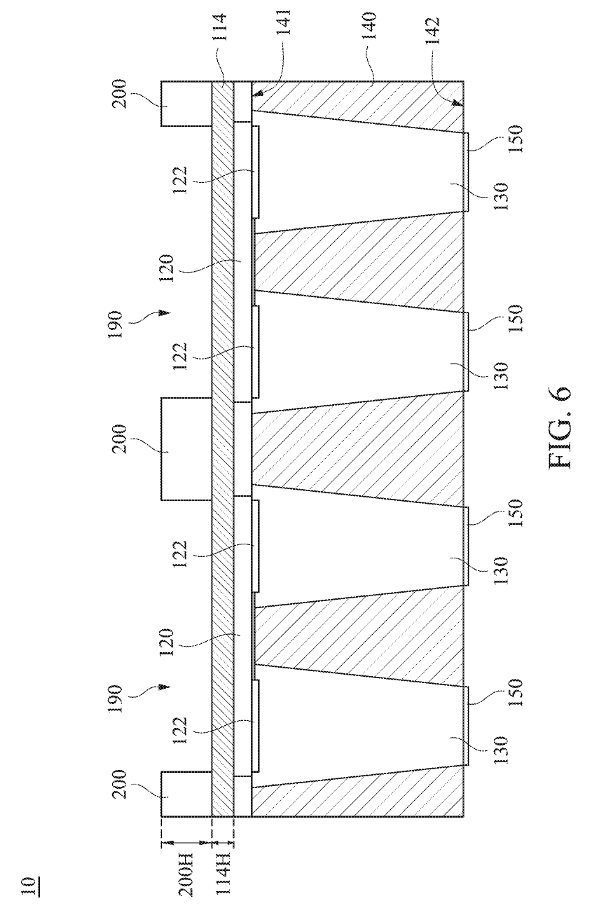

Then, a patterned shielding layer 200 is formed above the optical sensor unit 120, such that the optical sensor unit 120 is disposed between the patterned shielding layer 200 and the supporting layer 140, as shown in FIG. 6. It is understood that the patterned shielding layer 200 is used to define a light-receiving area. Specifically, the opening 190 of the patterned shielding layer 200 is located directly above the optical sensor unit 120, allowing the light passing through the opening 190 and received by the optical sensor unit 120. In other words, the vertical projection of the patterned shielding layer 200 onto the supporting layer 140 does not completely overlap with or only partially overlaps with the vertical projection of the optical sensor unit 120 onto the supporting layer 140.

In some embodiment, the step of forming the patterned shielding layer 200 above the optical sensor unit 120 may include thinning the substrate 112 of FIG. 5 first, and then etching the substrate 112 to form an opening 190, such that the opening 190 is located directly above the optical sensor unit 120, thereby forming the optical sensor module 10 as shown in FIG. 6. It is understood that the patterned shielding layer 200 is processed from the substrate 112 of FIG. 5. That is, the patterned shielding layer 200 includes the same material as the substrate 112. In the embodiment, when the patterned shielding layer 200 is part of the substrate 112 (e.g., including silicon), the thickness 200H of the patterned shielding layer 200 is 10 µm to 30 µm or 20 µm to 40 µm, for example, it can be 15 µm, 20 µm or 25 µm.

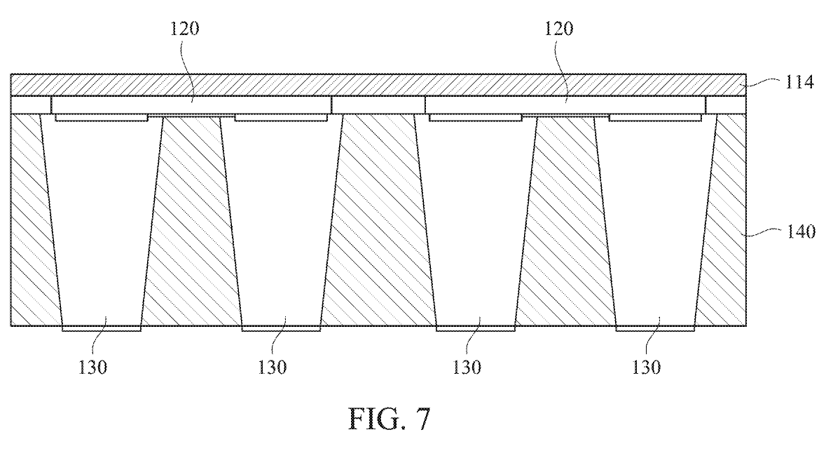

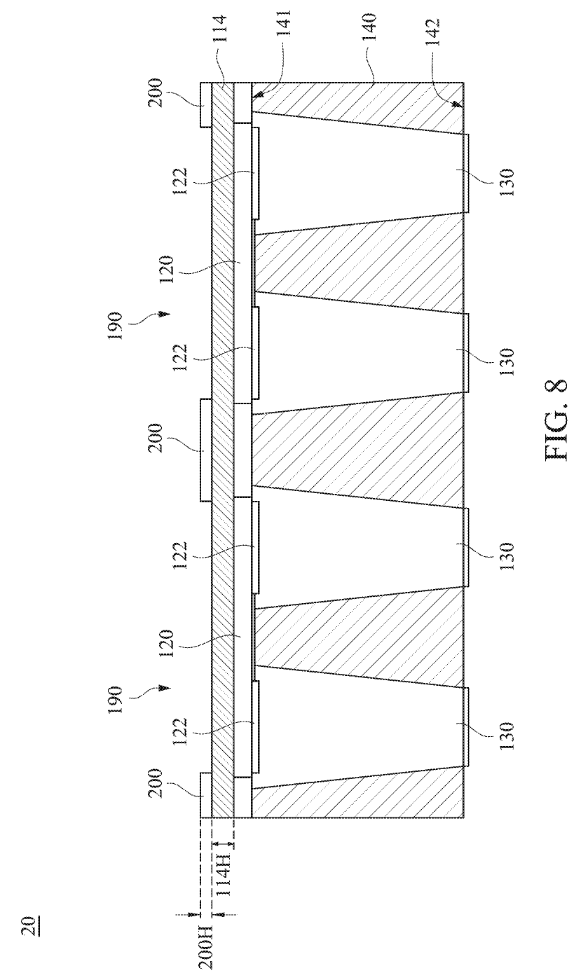

FIGS. 7 and 8 illustrate the cross-sectional schematic diagrams of the fabrication of an optical sensor module at different process steps according to other embodiments of the present disclosure. FIGS. 7 and 8 follow the process step described in FIG. 5. In another embodiment, the step of forming a patterned shielding layer 200 above the optical sensor unit 120 includes completely removing the substrate 112 to expose the etching stop layer 114, as shown in FIG. 7. Next, a patterned mask is formed on the exposed etching stop layer 114, and then the patterned mask is etched to form the patterned shielding layer 200, wherein the patterned shielding layer 200 includes an opening 190 located directly above the optical sensor unit 120, thereby forming the optical sensor module 20 as shown in FIG. 8. In the embodiment, the material of the patterned shielding layer 200 includes metal, photoresist, or other suitable light shielding materials, but the present disclosure is not limited thereto. For example, the metal includes molybdenum (Mo), chromium (Cr), chromium oxide, chromium nitride or other chromium compounds, nickel (Ni) and tungsten (W) alloy, titanium nitride, or other suitable metallic light shielding material, but the disclosure is not limited thereto. The photoresist includes non-metallic light shielding material such as carbon black, dark metal oxide, or dark dye.

In some embodiments, when the patterned shielding layer 200 includes metal, the thickness 200H of the patterned shielding layer 200 is 0.1 µm to 3 µm, for example, 0.5 µm, 1.0 µm, 1.5 µm, 2.0 µm, or 2.5 µm. In some embodiments, when the patterned shielding layer 200 includes photoresist, the thickness 200H of the patterned shielding layer 200 is 2 µm to 8 µm or 3 µm to 5 µm, for example, 3.5 µm, 4.0 µm, or 4.5 µm. It is understood that the better the light shielding properties of the material of the patterned shielding layer 200, the smaller its thickness can be.

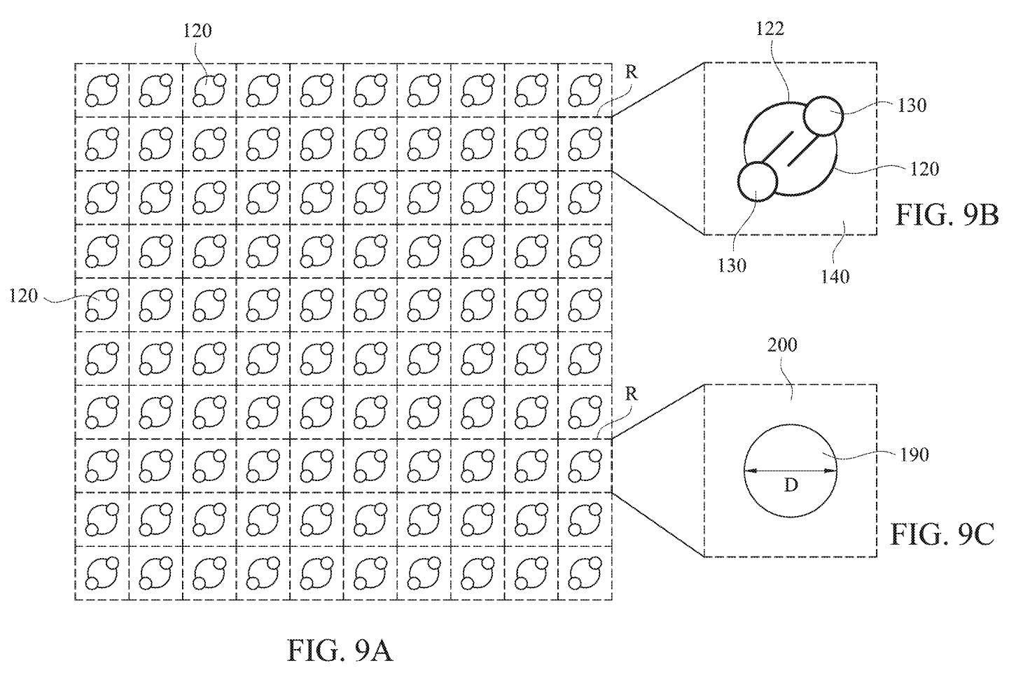

By means of the manufacturing method of the optical sensor module described above, the optical sensor modules 10 and 20 as provided in FIGS. 6 and 8 of the disclosure can be formed. FIG. 9A illustrates a top view of the optical sensor modules 10 and/or 20 according to an embodiment of the disclosure. FIGS. 9B and 9C illustrate the enlarged views of the region R in FIG. 9A. FIG. 9B illustrates a bottom view of the micro optical sensor unit 120 viewed from a side of the conductive pillar 130. FIG. 9C illustrates a top view of the micro optical sensor unit 120 viewed from a side of the opening 190.

Specifically, the optical sensor modules 10 and 20 include the supporting layer 140, one or more optical sensor units 120, the plurality of conductive pillars 130, and the patterned shielding layer 200. The supporting layer 140 includes an upper surface 141 and a lower surface 142 opposite each other. The optical sensor units 120 are disposed on the upper surface 141 of the supporting layer 140. The conductive pillars 130 penetrate through the upper surface 141 of the supporting layer 140 and extend to the lower surface 142. The conductive pillars 130 are electrically connected to the optical sensor units 120. The patterned shielding layer 200 is located above the optical sensor units 120, wherein the patterned shielding layer 200 includes one or more openings 190 located directly above the optical sensor units 120.

In some embodiments, the optical sensor modules 10 and 20 further include an insulating layer disposed between the optical sensor unit 120 and the patterned shielding layer 200, and the thickness 114H of the insulating layer is 1 µm to 5 µm. The insulating layer mentioned herein is the etching stop layer 114 mentioned above. Since the insulating layer (or the etching stop layer 114) includes a light-transmitting insulating material, such as silicon dioxide or silicon nitride, it does not affect the light collection of the optical sensor unit 120.

In some embodiments, the optical sensor modules 10 and 20 includes the plurality of optical sensor units 120 arranged in an array or a matrix, as shown in FIG. 9A. In some embodiments, the optical sensor unit 120 includes a plurality of contacts 122, such as P-type contacts and N-type contacts, and each conductive pillar 130 directly contacts each contact 122 to achieve electrical connection, as shown in FIG. 9B. In some embodiments, the width or diameter D of each optical sensor unit 120 is between 10 µm and 80 µm or between 40 µm and 60 µm, for example, 42 µm, 44 µm, 46 µm, 48 µm, 50 µm, 52 µm, 54 µm, 56 µm, or 58 µm. However, the shape of the optical sensor unit 120 is not limited to that shown in FIGS. 9A, 9B, and 9C, and other shapes are within the scope of the disclosure.

In some embodiments, the plurality of micro optical sensor units 120 may be arranged at intervals or continuously. When the plurality of micro optical sensor units 120 is arranged continuously, they may be formed in the same layer, such as a silicon layer. By locally forming an n-type region (not shown), a p-type region (not shown), and an i-type region (not shown) in the silicon layer, and forming the contacts 122 at positions corresponding to the n-type and p-type regions, electrons and holes in the micro optical sensor unit 120 may migrate toward the n-type and p-type regions respectively when receiving light signals, thereby generating a photocurrent for detection. The contacts 122 respectively electrically connected to the n-type and p-type regions may be complementary metal wires, which are connected to an external circuit through the conductive pillars 130.

In some embodiments, the patterned shielding layer 200 includes silicon, metal, or photoresist. In some embodiments, when the patterned shielding layer 200 includes silicon, the thickness 200H of the patterned shielding layer 200 is 10 µm to 30 µm or 20 µm to 40 µm. In some embodiments, when the patterned shielding layer 200 includes metal, the thickness 200H of the patterned shielding layer 200 is 0.1 µm to 3 µm. In some embodiments, when the patterned shielding layer 200 includes photoresist, the thickness 200H of the patterned shielding layer 200 is 2 µm to 8 µm or 3 µm to 5 µm. The formation methods, materials, and related feature details of each element have been described in detail above and will not be repeated here.

The foregoing description is merely exemplary embodiments of the present invention, and any equivalent changes and modifications made in accordance with the scope of the claims of the present invention shall fall within the scope of the present invention.

What is claimed is:

1. An optical sensor module, including:
a supporting layer, including an upper surface and a lower surface opposite to each other;
an optical sensor unit, disposed on the upper surface;
a plurality of conductive pillars, penetrating the supporting layer and electrically connected to the optical sensor unit; and
a patterned shielding layer, located above the optical sensor unit, and including an opening located directly above the optical sensor unit.

2. The optical sensor module according to claim 1, further including an insulating layer disposed between the optical sensor unit and the patterned shielding layer.

3. The optical sensor module according to claim 1, wherein the optical sensor unit includes a plurality of contacts which directly contacts the plurality of conductive pillars.

4. The optical sensor module according to claim 1, wherein the patterned shielding layer includes silicon, metal, or photoresist.

5. A method for manufacturing an optical sensor module, including:
forming an etching stop layer on a substrate;
forming an optical sensor unit on the etching stop layer;
forming a plurality of conductive pillars on the optical sensor unit;
forming a supporting layer among the plurality of conductive pillars; and
forming a patterned shielding layer on the optical sensor unit.

6. The method for manufacturing the optical sensor module according to claim 5, wherein the step of forming the patterned shielding layer includes:
thinning the substrate; and
etching the substrate to form an opening located directly above the optical sensor unit.

7. The method for manufacturing the optical sensor module according to claim 5, wherein the step of forming the patterned shielding layer includes:
removing the substrate to expose the etching stop layer;
forming a patterned mask on the etching stop layer; and
etching the patterned mask to form the patterned shielding layer which includes an opening located directly above the optical sensor unit.
